(19) United States
(12) Patent Application Publication
(10) Pub. No.: US 2026/0119778 A1
(43) Pub. Date: Apr. 30, 2026

(54) Method and System for Estimating Parasitic Capacitance Using Localized Weighting and Federated Learning Model

(71) Applicant: GenChip.AI Inc., Sunnyvale, CA (US)

(72) Inventors: Sreekar Bathula, San Jose, CA (US); Eric Panning, Portland, OR (US)

(21) Appl. No.: 19/376,681

(22) Filed: Oct. 31, 2025

Related U.S. Application Data
(60) Provisional application No. 63/714,761, filed on Oct. 31, 2024.
(60) Provisional application No. 63/714,754, filed on Oct. 31, 2024.
(60) Provisional application No. 63/714,793, filed on Oct. 31, 2024.
(60) Provisional application No. 63/714,797, filed on Oct. 31, 2024.
(60) Provisional application No. 63/714,796, filed on Oct. 31, 2024.
(60) Provisional application No. 63/714,773, filed on Oct. 31, 2024.

(51) Int. Cl. G06F 30/398; G06F 30/33; G06F 30/343; G06F 30/347; G06N 20/00

(52) U.S. Cl. CPC G06F 30/398; G06F 30/33; G06F 30/343; G06F 30/347; G06N 20/00

(57) ABSTRACT

A method and system for parasitic extraction in semiconductor layouts using localized weighting and a federated learning model. The process involves receiving a layout design of an integrated circuit, generating nodes representing geometrical points, and assigning weights based on node location and material. A self-attention network identifies a subset of nodes for parasitic extraction, generating extraction data linked to physical design patterns. The method incorporates this data into a machine learning model for parasitic extraction, updating the machine learning model with layouts from various process design kits. The system aggregates and converts extraction data into a 2D format for graphical display, enhancing design analysis and prediction accuracy.

### CROSS-REFERENCE TO RELATED APPLICATIONS

This application claims the benefit of and priority to U.S. Provisional Patent Application Ser. No. 63/714,754 entitled “Method for Estimating Parasitic Capacitance Using Spatial Localization,” 63/714,761 entitled “Method and System for Estimating Parasitic Capacitance Using Localized Weighting and Federated Learning Model,” 63/714,793 entitled “Method for Transistor Order Placement Using Graph Neural Network Recursive Model,” 63/714,797 entitled “Method for Transistor Layout Generation Using Graph Neural Network Recursive Model,” 63/714,796 entitled “Method for Transistor Layout Design Checking Using Reinforcement Learning,” and 63/714,773 entitled “Method For Transistor Layout Design Using 3D Model Representation in Latent Space,” all of which were filed on Oct. 31, 2024 and which applications are expressly incorporated herein by reference in their entirety.

### BACKGROUND OF THE INVENTION

The present disclosure generally relates to electronic design automation for the design and manufacture of integrated circuits and microelectronics.

Electronic design automation (EDA) includes software tools for designing electronic systems such as integrated circuits. With semiconductor chips having billions of components or more, computer-aided tools are essential for logical design, physical design, and manufacturing processes. Integrated circuit design includes many steps, typically beginning with a system specification. After system specification, several logical design steps can be completed based on that specification including register transfer level design, functional verification, timing simulation, and netlist generation. After logical design, physical design steps can be executed to generate a physical layout of the integrated circuit. There are many physical design steps including partitioning, floor planning, placement, clock tree synthesis, and signal routing, among others. After a physical layout is verified, then an integrated circuit can be fabricated using the physical layout generated from EDA tools.

EDA tools are helpful to optimize the production process for semiconductor devices, such as integrated circuits. Such optimization involves designing semiconductor layouts and evaluating properties of the designs. Important properties assessed include resistance and capacitance, which are instrumental in deriving estimates for Power, Performance, Area, and Cost (PPAC) of a semiconductor device. The accurate estimation of these properties can significantly influence cost savings. Various tools are employed in this process to perform detailed 3D assessments of the designs, enabling precise point-to-point calculations of resistance and capacitance. During the physical design process of an integrated circuit, a significant variable to generating an acceptable design that meets logical constraints and system specifications is parasitic capacitance. Parasitic capacitance is the unwanted, yet unavoidable, capacitance that exists between conductive parts of an electronic circuit. Parasitic capacitance can cause the behavior of chip components to depart from ideal performance. The calculation of resistance and capacitance thus plays an important role in determining power and performance values.

Physical layout design for integrated circuits is often complicated, challenging, and time consuming. A given logical design can identify the logical circuits and transistors to be included in a particular design, but then identifying a physical placement layout of transistors—that meets device specifications—is challenging because of the millions or more different layouts possible, each with respective advantages and disadvantages.

### SUMMARY OF THE INVENTION

Techniques disclosed herein include methods and systems that improve the estimation of capacitance and resistance in semiconductor layout designs for better identifying power, performance, area, and cost metrics. Techniques include calculating these two parameters using various technologies which can include attention networks, and federated dropout mechanisms, among others.

Maintaining continuous, accurate, and precise operation of semiconductor design tools is essential for maximizing device yield. These tools, however, often require extensive processing time due to the rigorous calculations needed to ensure devices are manufactured correctly. These calculations provide important feedback for refining initial device designs. Delays and yield losses can significantly decrease productivity and increase the depreciation costs of processing tools. Furthermore, these tools can impact the productivity of engineers and limit opportunities for optimizing designs.

Conventional tools that perform parasitic extraction (PEX) calculations take an initial layout as input, actuate or simulate the process to create a complete semiconductor device, and then calculate the resistance and capacitance values based on the process and design variables. These calculations are then analyzed to correct or improve the layout. This iterative process continues until a desired value set of a design is achieved.

Techniques herein, in contrast, use a machine learning process that receives a layout as input and uses localization weighting and transfer learning to predict PEX values. Transfer learning can be realized using segments or components of circuit designs. This approach processes higher-order cells and dies more efficiently, significantly speeding up the calculations and improving overall productivity.

One general aspect includes a method of training a parasitic extraction machine learning model. The method also includes receiving a first layout design of at least a portion of an integrated circuit, the first layout design including geometrical specifications, logical specifications, and material specifications. The method includes identifying geometrical locations from the first layout design as nodes for inclusion in parasitic extraction calculations. A weight is assigned to each node based on relative node location and node material. Parasitic extraction is performed on the first layout design using a self-attention network based on the nodes and corresponding assigned weights to generate parasitic extraction data corresponding to geometrical layout segments. The method also includes labeling the geometrical layout segments and linking corresponding parasitic extraction data to the labeled geometrical layout segments. The parasitic extraction data is incorporated into a machine learning model that stores parasitic extraction data linked to the labeled geometrical layout segments.

Other embodiments may include one or more of the following features. Accumulating parasitic extraction data in the machine learning model for a plurality of geometrical layout segments from multiple layout designs such that subsequent performance of parasitic extraction of a candidate layout design using the machine learning model includes use of the stored parasitic extraction data linked to the labeled geometrical layout segments that physically match the geometrical layout segments from the candidate layout design. Identifying a particular geometrical layout segment having a pattern appearing repeatedly from the first layout design and having corresponding parasitic extraction data values that vary relative to each other, and selecting a representative parasitic extraction value for the particular geometrical layout segment. Updating the machine learning model using layout designs corresponding to a first process design kit, and performing parasitic extraction for the candidate layout design using the machine learning model and stored parasitic extraction data from the first process design kit, with the candidate layout design being generated based on a second process design kit. The method may include identifying intermediate nodes between two end point nodes in a given geometrical structure region and excluding the intermediate nodes from parasitic extraction calculations when the intermediate nodes modify parasitic values of the given geometrical structure region by less than a predetermined threshold value. The method may include calculating second parasitic extraction data for the given geometrical structure region by excluding the intermediate nodes from calculation, and linking the second parasitic extraction data to the given geometrical structure region and adding the parasitic extraction data to the machine learning model. The method may include excluding nodes from parasitic extraction having an assigned weight below a predetermined value. Implementations of the described techniques may include hardware, a method or process, or computer software on a computer-accessible medium.

### BRIEF DESCRIPTION OF DRAWINGS

This disclosure will be understood more fully from the detailed description below and from the accompanying figures of embodiments of the disclosure. The figures are used to facilitate understanding of embodiments of the disclosure and do not limit the scope of the disclosure to these specific embodiments. The figures are not necessarily drawn to scale.

FIG. 1 shows a system architecture for a transfer learning loop used herein.

FIG. 2 is a flow diagram of data generation for resistance-capacitance estimation.

FIG. 3 is a schematic and flow diagram of systems herein for efficient parasitic capacitance estimation.

FIG. 4 is a diagram illustrating federated learning for updating node weights herein.

FIG. 5 is a flow chart of example embodiments herein.

FIG. 6 is a flow chart of example embodiments herein.

FIG. 7 is a representation of labeled parasitic extraction data.

FIGS. 8A-8C are perspective views of example wiring layouts to illustrate efficient parasitic extraction techniques herein.

FIG. 9 depicts a representative diagram of an example computer system in which embodiments of the present disclosure may operate.

### DETAILED DESCRIPTION

In the field of electronic design automation, optimizing the production process for semiconductor devices, such as integrated circuits, remains a challenge. The manufacturing phase involves designing semiconductor layouts and evaluating properties like resistance and capacitance. These properties are important for deriving estimates for power, performance, area, and cost metrics of semiconductor devices. Accurate estimation of these properties can significantly influence cost savings and efficiency. Various tools perform detailed three-dimensional assessments of designs, enabling precise point-to-point calculations of resistance and capacitance. These calculations play a significant role in determining power and performance values, impacting the overall design and manufacturing process.

Current methods for parasitic extraction calculations often involve taking an initial layout as input, simulating the process to create a complete semiconductor device, and then calculating resistance and capacitance values based on process and design variables. This iterative process continues until a desired value set is achieved. These conventional tools, however, require extensive processing time due to the rigorous calculations needed to ensure devices are manufactured correctly. Delays and yield losses can significantly decrease productivity and increase the depreciation costs of processing tools. Furthermore, these tools can impact the productivity of engineers and limit opportunities for optimizing designs.

The techniques disclosed herein introduce a machine learning process that receives a layout as input and uses localization weighting and transfer learning to predict parasitic extraction values. This approach processes higher-order cells and dies more efficiently, significantly speeding up calculations and improving overall productivity. By employing a self-attention network, the method identifies the most important parameters for prediction, considering the effects of neighboring devices, nets, or materials on the given material. The use of a localized weighting process assigns a weight to each node location based on device, net, or material, reducing the number of parameters considered and improving efficiency. Transfer learning adapts the model to various processes, enhancing adaptability and generalizability across different models without accessing confidential data.

Techniques herein include methods of training a model for more efficient estimation of parasitic capacitance and resistance values for accelerating electronic design automation. Such techniques use a relatively large amount of semiconductor parasitic extraction data (PEX data) to train a machine learning model capable of predicting or estimating resistance and capacitance values of logical or virtual designs, prior to fabrication. Techniques herein can generate nodes and labels for material locations within a semiconductor device layout. PEX systems can calculate values such as resistance and capacitance between any two points in the semiconductor device, or a model of a layout design. This calculation process improves efficiency by focusing on particular nodes or particular labels that significantly impact design correction and improvement. In other words, techniques herein include parameter reduction processes to reduce calculation time and inference times.

Parameter reduction herein is achieved through various techniques. One technique is a weighting process, in which each node or node location is assigned a weight (relative constant) based on the device, net, and/or material. This data or weighting is then fed into an attention network to identify parameters deemed most important for accurate and efficient prediction. The attention network is used to capture the effects of neighboring devices or nets or materials or other parameters on the given subject material. Materials can include different conductors and surrounding dielectrics. This parameter-specific attention and weight assignment is referred to herein as localized weighting. Weighting can also be based on distance or adjacency to a give point (starting point) from with parasitic extraction is being evaluated. Moreover, regarding assigning node importance, after processing with the attention network, a main graph can be refined by selecting nodes and edges based on their predicted importance scores and the influence of their neighbor nodes and edges. This results in a simplified graph with fewer, but more relevant, nodes and connections.

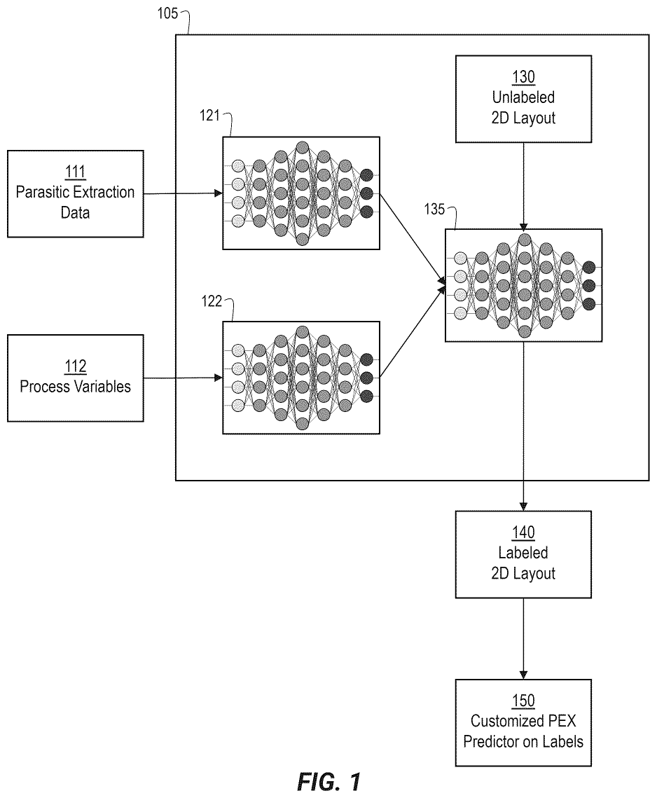

FIG. 1 shows a system architecture for a transfer learning loop 105. This architecture integrates parasitic extraction data 111 and process variables 112 as inputs to enable prediction capabilities of semiconductor layouts. The parasitic extraction data 111 provides information about the resistance and capacitance values (and inductance) within the semiconductor device, while the process variables 112 identify conditions under which the device operates and can include materials used and other design constraints.

The architecture includes latent translation component 121 and 122, which process the parasitic extraction data 111 and process variables 112, respectively. These components transform the input data into a format suitable for further analysis and prediction. Various models can be selected for use here. The transformed data is then fed into a self-attention network 135, which identifies the most significant parameters for predicting parasitic values. This network links relationships between different nodes and materials within the semiconductor layout to enhance prediction accuracy and/or efficiency.

Unlabeled 2D layout 130 serves as an initial representation of a semiconductor design, lacking specific labels for node locations or layout design segments. Unlabeled 2D layout 130 can include bounds of multiple polygons along with corresponding layer information, which can be included or embodied as a stack of layers with bounds. The self-attention network 135 processes this layout to generate a labeled 2D layout 140, which includes detailed annotations of material locations and their corresponding parasitic values. This labeled layout can include sub-set or segments of the layout as geographical segments. This labeled layout aids in visualizing and analyzing the design, enabling more precise predictions and optimizations as well as providing shortcuts for pattern matching during subsequent analysis after training. Techniques can include displaying this labeled data.

The labeled 2D layout 140 is then used by a customized PEX predictor on labels in step 150, which can include fewer labels than initially labeled in 140. This component focuses on reducing the number of labels required for accurate predictions, thereby improving computational efficiency. By using and reducing the labeled data, the customized PEX predictor of step 150 improves efficiency of the parasitic extraction process (processing time), as well as an improvement in predictions aligning closely with the actual physical design of the semiconductor device once microfabricated.

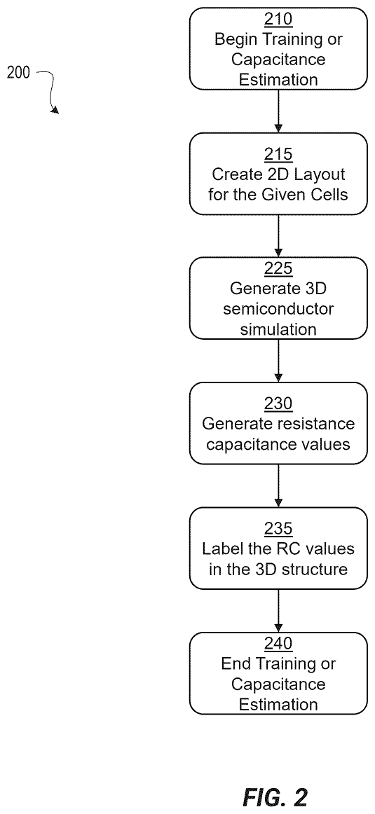

FIG. 2 shows method 200 as an example embodiment for estimating parasitic capacitance and resistance in semiconductor layouts. The method 200 (and/or associated system) can be implemented by a system designed for electronic design automation, focusing on training models and estimating capacitance values. At step 210, the method 200 begins training or capacitance estimation.

At step 215, method 200 creates a 2D layout for the given transistors. This can involve accessing a design file, such as a GDS file that represents the transistors (or, optionally, standard cells) in two dimensions, to prepare input for further analysis. At step 225, the method 200 generates a 3D semiconductor simulation. Note that the transistors can be considered a 2D layout, but with transistors modeled and wiring modeled this is a 3D structure. This simulation models the semiconductor device in three dimensions, allowing for a more comprehensive analysis of the semiconductor device's properties and behavior. At step 230, the method 200 generates resistance and capacitance values. This step calculates the electrical properties of the semiconductor layout, focusing on the resistance and capacitance between different points in a semiconductor 3D simulated design or a GDS layout, though other electrical values can be calculated as well.

At step 235, the method 200 labels the resistance and capacitance values in the 3D structure. This can include annotating the 3D model with the calculated values, facilitating visualization and further analysis. At step 240, the method 200 ends training or capacitance estimation. Not also that the labeled structures can be separated into segments as a top-down image that would essentially be a 2D image segment of a larger design structure. This can include annotating a 3D model for inspection from various views.

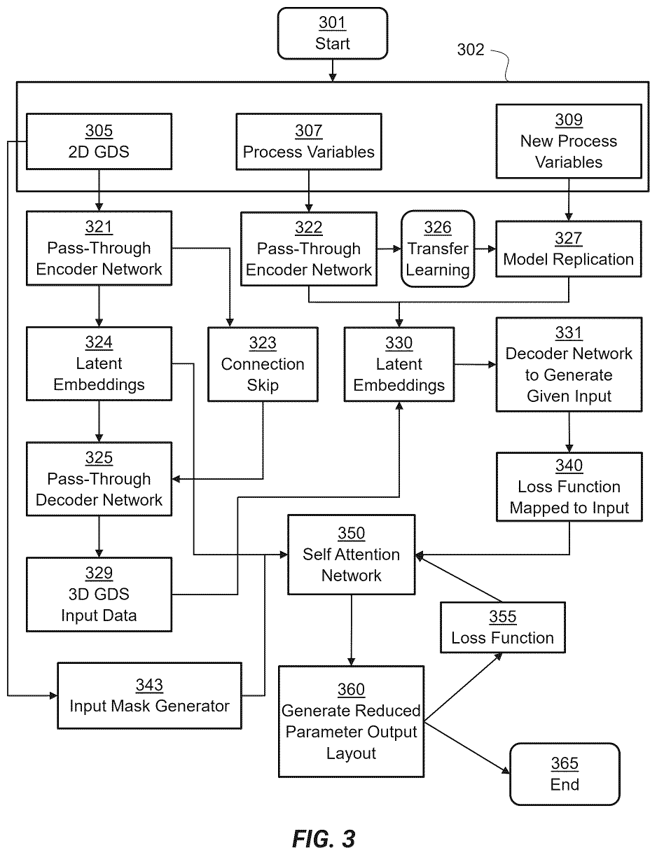

Referring now to FIG. 3, a schematic system diagram and process flow illustrates how various embodiments herein can be combined for improved efficiency in estimating parasitic capacitance in semiconductor device layouts. At step 301, the process starts and initiates a sequence for estimating parasitic capacitance using a neural network-based model that may include federated learning. Inputs 302 serve as the foundational entry point for the system and include three primary data sources: (1) the 2D GDS layout input 305, (2) the process variables 307, and (3) the new process variables 309.

The 2D GDS Input 305 provides a two-dimensional representation of the semiconductor layout. This 2D GDS (Graphic Design System) input can include polygon shapes, layer assignments, feature sizes, spacings, and metal widths. This geometric data is parsed into an internal representation such as a planar graph with nodes representing conductor edges or via endpoints for subsequent feature extraction and encoding. The process variables 307 define the operating conditions and fabrication parameters of the semiconductor device, including layer dielectric constants, ambient temperature, supply voltage, feature size scaling, metal resistivity, doping concentration, oxide thickness, and interlayer capacitance multipliers. These variables directly influence the electromagnetic behavior of the layout and are beneficial to accurate capacitance prediction. The new process variables 309 introduce dynamic parameters that may emerge during model usage or retraining, such as process drift, changes in fabrication recipes, variations in ambient conditions, or user-specified constraints. These are incorporated into the system via input streams or metadata, enabling the model to adapt to evolving process conditions and maintain predictive accuracy.

The pass-through encoder network 321 processes the 2D GDS input 305, transforming the raw geometric/layout data into a latent space representation. In one embodiment, this encoder is a graph neural network (GNN) that takes nodes (e.g. polygon edge, via, metal segment) and edges (adjacency, proximity, nets) and computes node embeddings using several layers (e.g., 35 message passing rounds), with non-linear activations (Rectified Linear Unit, Leaky Rectified Linear Unit) and batch normalization. The network may embed both geometric features (length, width, density) and context features (nearness to other nets, dielectric layer above/below, etc.). Similarly, the pass-through encoder network 322 processes the process variables 307 (and new process variables 309), mapping them to a latent vector or embedding via a fully connected (dense) neural network (multi-layer perceptron), normalizing input variables, optionally applying embedding layers for categorical variables (e.g., material type), and combining into a fixed-size vector. The connection skip 323 provides skip connections from earlier layers of encoders (or between corresponding encoder/decoder stages), enabling bypass of some layers to allow residual paths, reduce vanishing gradient problems, and help preserve fine structural detail from the layout. For example, the encoder's first and/or second layers may be directly connected to corresponding decoder layers.

The latent embedding 324 is the result of combining the outputs of the layout encoder (pass-through encoder network 321) and process variables encoder (pass-through encoder network 322), for example, via concatenation or elementwise addition, optionally followed by projection (dense layers) and optional normalization. This embedding captures the joint influence of geometry, material properties, and layout context in a compact numerical form (e.g. a vector of dimension 128-1024 depending on a given embodiment). The pass-through decoder network 325 reconstructs from the latent embedding 324 an internal representation that is aligned with the input layout specification for purposes such as predicting parasitic capacitances or producing intermediate layout predictions. This decoder may mirror the encoder architecture (e.g., reverse message passing, graph un-pooling) and then map back to per node or per edge values: e.g., predicted capacitance between node pairs, or mapping back to GDS shapes or layout features.

The transfer learning module 326 allows the model trained on one or more Process Design Kits (PDKs), which include design rules, device models, and process parameters that define the foundry's manufacturing capabilities to be adapted to new PDKs. In one embodiment, the model's encoder/decoder weights are pretrained on a large dataset of layouts and process variables from multiple foundries, then fine-tuned on a smaller dataset for the target PDK. In some embodiments, input can include process rules that define a foundry process capability. Hyperparameters (for example, learning rates and regularization) are chosen to avoid overfitting. The model replication 327 component duplicates the trained/fine-tuned model, allowing parallel or distributed inference or evaluation over multiple layout instances or multiple process variable sets. For example, once the model is trained, multiple replicas can run inference on different candidate layouts simultaneously to speed up design evaluation.

The 3D GDS input data 329 provides an optional but more detailed input form: three dimensional layout data including height/thickness of layers, via stacks, interlayer dielectrics, volumetric features. Such 3D input may come from 3D layout tools or be inferred from stacking of 2D layers plus material thickness. This latent embedding 330 captures features of the 3D GDS input data 329, this 3D data is processed to yield latent embeddings 330 by a 3D encoder network (e.g., a volumetric graph or tensor network) that captures interlayer coupling, parasitic effects in the vertical direction, and thus improves accuracy of predicted capacitances (especially coupling capacitance between layers).

The decoder network 331 reconstructs the latent embedding 330 (from the 3D encoder) into predicted layout or capacitance outputs aligned with the original 3D specification: e.g., node to node capacitance, interlayer coupling values, or predicted parasitic values for 3D features. The input mask generator 343 reduces dimensionality by selecting a subset of nodes/features or edges considered for detailed estimation. For example, selections can include masking out features below some width threshold, or far from nets of interest, or selecting high impact nets based on distance, adjacency, or previous estimates. Masking may also be based on a learned criterion (attention scores, or a small network that predicts node importance). This helps reduce computational cost without sacrificing much accuracy.

The loss function 340 evaluates the accuracy of the model's predictions compared to rigorous TCAD (Technology Computer-Aided Design) simulation parasitic extraction (PEX) or simulation data. Loss terms may include mean squared error (MSE) of capacitance values per node pair, percent error, or other domain specific error metrics. Regularization terms (L2 weight decay, possible edge connectivity penalties) may be included. The “mapped to input” phrasing refers to mapping predicted values back to the same layout or nodes used in input so that error is computed over corresponding elements.

The self-attention network 350 identifies relationships or interactions among features. For example, the self-attention network 350 can allow each node in the latent graph embedding to attend to neighboring nodes, nets, or material layers to modulate how much influence each neighbor has on local parasitic behavior. In one embodiment, this is implemented similarly to transformer style attention over graph nodes, or over spatial patches of layout, where attention weights are learned. The loss function 355 further refines the model's predictions by applying auxiliary or combined objectives, for example consistency loss across multiple PDKs, smoothness of capacitance across spatial transitions, or penalty for embedding divergence. Together, loss function 340 and loss function 355 ensure both raw prediction accuracy and generalization.

Step 360 generates an output layout having reduced parameters. That is, from the decoder outputs (whether from 2D only, 3D, or combined), the method produces a layout (or layout metadata) that retains or highlights only parameters or features considered most relevant to parasitic performance. For example, output can be constrained to a fixed percentage (for example, the top 10% to 20%) of nets or node pairs with highest predicted parasitic capacitance, or only features within a threshold distance to critical nets, or limiting outputs to nodes/features above a certain size or width. This reduced parameter layout may omit or suppress less important features in downstream PEX or design checks to speed up design iterations. At step 365, the process ends. This process may be repeated in cycles (retraining, new data) for further refinement, or invoked for each new layout or new process variable set.

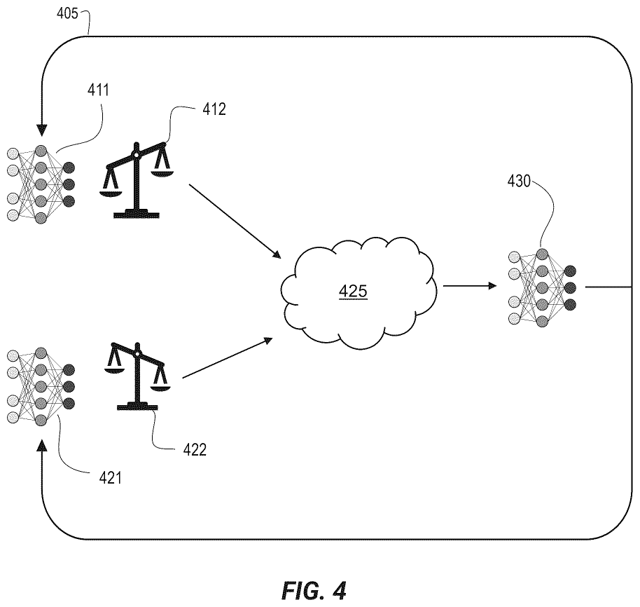

FIG. 4 is a diagram illustrating federated learning for updating node weights. The federated learning process 405 initiates with input node networks 411 and 421. These networks represent distributed data sources that contribute to the learning process without sharing raw data, ensuring privacy and security. Input node network 411 undergoes a weighting process 412. This process assigns weights to the data based on specific criteria, enhancing the relevance and accuracy of the information used in the learning model. Similarly, the input node network 421 is subjected to a weighting process 422, which performs a comparable function, ensuring that the data from this network is also optimally used.

Both weighted inputs are transmitted to a cloud server 425 or other data repository. The cloud server acts as a central hub, aggregating the weighted data from multiple sources. This aggregation allows for a comprehensive analysis and integration of diverse data sets, facilitating a more robust learning model. Once the data is aggregated, the learning averaging 430 component processes the combined information. This component calculates the average of the updated weights, refining the model's parameters to improve the model's predictive capabilities. The updated model is then distributed back to the input node networks or other predictive models to continually improve and train the models.

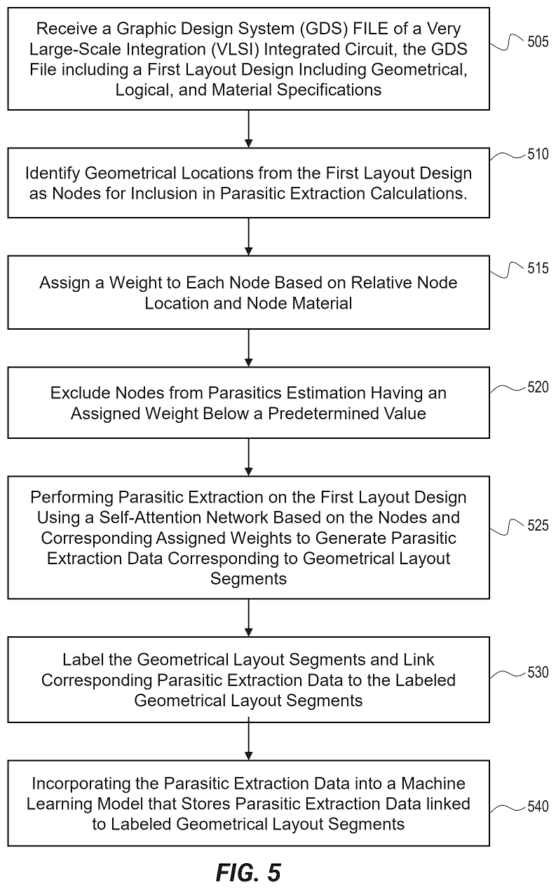

FIG. 5 is a flow chart illustrating an example embodiment herein. At step 505, a graphic design system (GDS) file of a very large-scale integration (VLSI) integrated circuit is received. The graphic design system file includes a first layout design including geometrical, logical, and material specifications. The GDS file (or equivalent) of the VLSI circuit serves as the initial input, providing a representation of the integrated circuit's design. The layout design encompasses various specifications that define the structure and functionality of the circuit, forming the basis for subsequent parasitic extraction. Layout design can be received as a netlist, Graphic Design System file such as GDSII, or other similar specification of a circuit design to be evaluated physically.

Next, in step 510, the system identifies geometrical locations from a first layout design as nodes for inclusion in parasitic extraction calculations. This step involves analyzing the layout design to determine specific points or nodes that are relevant for parasitic extraction. The identification process can focus on nodes that significantly impact the electrical properties of the design, ensuring accurate and efficient calculations. Selection criteria can be based on geometric corners, mid-points of lines, connection points and other relevant locations.

In step 515, once the nodes are identified, the system assigns a weight to each node based on node location and node material. This can be based on relative node location, such as relative to a point from which parasitic extraction will be calculated. This weighting process evaluates the importance of each node in relation to the node's position and the material properties. By assigning weights, the system prioritizes nodes that have a greater influence on parasitic values, optimizing the estimation process. Assigned weights can be a constant or other indicator of relative importance. Note that a node's assigned weight can be relative to a point being evaluated in the design, with closer nodes having a greater weight for a point being evaluated. Embodiments can also include updating a node weight assignment model based on prediction accuracy.

Embodiments can include identifying intermediate nodes between two end point nodes in a given structural region that, when excluded from parasitic extraction, modify parasitic extraction data by less than a predetermined threshold. In another embodiment, a circuit solver is used and configured to reduce complexity of a graph by determining nodes positioned between a specified start point and end point within the graph representation. This is one technique to reduce a number of nodes being considered, such as intermediate connections, or otherwise simplifying such as when determining a total resistive value. Other embodiments can calculate second parasitic extraction data for the given structural region by excluding the intermediate nodes from calculation, and linking the second parasitic extraction data to the particular structural region and adding the parasitic extraction data to the machine learning model. Embodiments can include identifying intermediate nodes between two end point nodes in a given structural region and including the intermediate nodes from parasitics estimation when the intermediate nodes modify parasitic values of a structural region by more than a predetermined threshold or other criterion. In other embodiments, parasitic extraction data can be accumulated in the machine learning model for a plurality of physical design segments such that subsequent performance of parasitic extraction in a second layout design uses stored parasitic extraction data from matched physical design segments. The model becomes more accurate with more accumulated layout segments.

In step 520, the system can exclude nodes from parasitic extraction having an assigned weight below a predetermined value. Filtering included nodes by value can effectively exclude nodes beyond a certain distance (length of conductor). This step reduces an initial set of nodes considered in the calculations, limiting to those nodes with a relative weight deemed significant enough or that reduces processing time by a desired amount compared to complete parasitic extraction evaluation. By filtering out less impactful nodes, the system enhances computational efficiency and accuracy in estimating parasitic values.

In step 525, parasitic extraction is performed on the layout design using a self-attention network based on the identified nodes and corresponding assigned weights. Self-attention networks include machine learning techniques to determine relative importance of components. Parasitic extraction can include the calculation/estimation of parasitic effects on an electronic circuit as a result of a particular layout. This can include calculating parasitic capacitances, parasitic resistances, and parasitic inductances, which is used to evaluate device performance of the particular design. This generates parasitic extraction data corresponding to particular physical design segments. The self-attention network analyzes the relationships between nodes, considering their weights and interactions to predict parasitic values. This network leverages advanced machine learning techniques to improve the precision of parasitic extraction as well as identify the most important relationships to include when performing parasitic extraction. Note that equations and tools for calculating capacitance, resistance, and inductance are known. Note that conventional processors and computer systems can be used for executing methods disclosed herein. By implementing a localized weighting system herein, parasitic extraction can be greatly accelerated. Note that there may be a relatively small reduction in accuracy from reduced and restricted parameters or inputs being considered, but the time improvement will be valuable to quickly evaluate millions or more candidate layouts to find a relatively small number of layouts with desired PEX data to evaluate more thoroughly.

In step 530, the system labels geometrical layout segments and links corresponding parasitic extraction data to the labeled geometrical layout segments. In this way, relatively small segments of a geometric design can be stored with parasitic extraction data for quick retrieval for matching segments. Circuits have different physical designs, but reducing the geometrical design into small enough segments means that there will be segments that repeat in new circuit designs and can benefit from using parasitic extraction data already extracted for a particular design segment. These geometrical layout segments can be represented as or stored as a set of nodes or collection of nodes, which can be merged nodes or reduced nodes, with the selected, eliminated or merged nodes being based on a weighting.

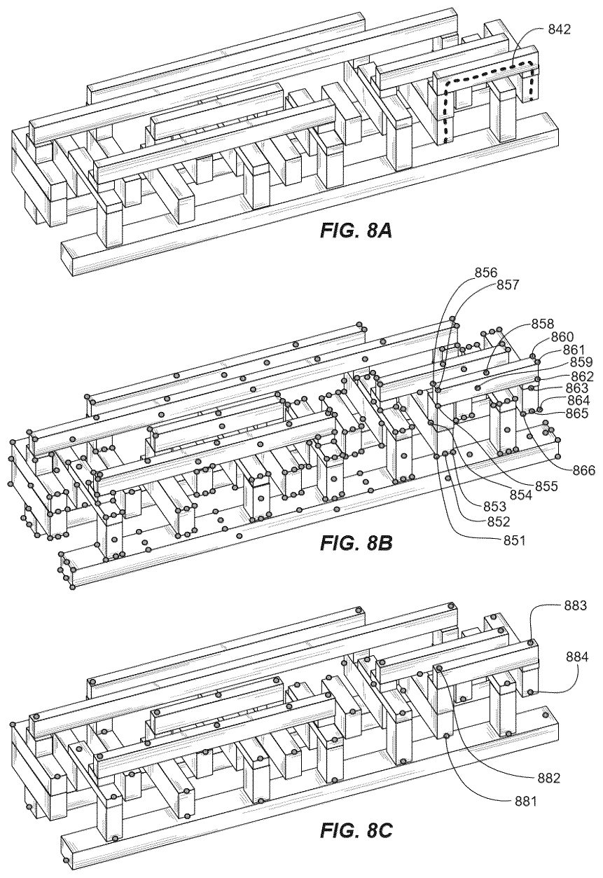

FIG. 8 illustrates geometric point modeling and node selection. FIG. 8A is a perspective view of an example physical layout of wiring for a given circuit, circuit element, or standard cell or portion thereof. FIG. 8B shows identified nodes from geometrical points based on a given design density. FIG. 8C then shows a subset of the nodes selected for use in parasitic extraction. As a simplified, non-limiting example, FIG. 8A includes a geometrical layout segment 842, which can be a wiring segment. FIG. 8B shows potential nodes 851 through 865 which can be nodes along or part of the geometrical layout segment. FIG. 8C shows nodes 881, 882, 883, and 884 which now represent the geometrical layout segment. Note that compared to FIG. 8B, several of the initial or potential nodes have been eliminated or merged, resulting in fewer nodes. This can include removing or merging some of the nodes considered less important for performing efficient parasitic extraction to a sufficiently accurate level. A geometrical layout segment, then, can comprise merged nodes or grouped nodes.

In step 540, the system can incorporate the parasitic extraction data into a machine learning model that stores parasitic extraction data linked to physical design segments. This integration step ensures that the extracted data is systematically organized and accessible for future reference. The machine learning model serves as a repository, linking the data to specific design segments, facilitating ongoing analysis and optimization of the integrated circuit design.

Embodiments can include identifying a particular structural segment having a pattern appearing repeatedly from the first layout design having corresponding parasitic extraction data values within a predetermined variance relative to each other. A pattern can be identified as appearing repeatedly if is appears more than a predetermined number of times or, if this can be based on a repetition amount identified as statistically significant. The machine learning model can be updated with the particular structural segment and corresponding parasitic extraction data. In other words, in the many candidate layouts, there will be repeating structural segments, which can be relatively simple shape patterns, that can be stored with corresponding PEX data. For example, this might be a line segment (wire) of a particular length that has a couple of 90 degree turns or an intersection of four metal lines of a certain critical dimension, or a wire of a particular length between two standard cells or between two transistors. This becomes a fingerprint segment, so that when evaluating new candidate layouts and matching segments are found, stored parasitic extraction data can be quickly recalled without needing to recalculate, thereby accelerating subsequent processing and analysis.

Embodiments can include updating the machine learning model using layouts corresponding to a first process design kit and estimating parasitics in a second layout design from a second process design kit using the machine learning model. The machine learning model can be updated using layouts corresponding to multiple process design kits. Thus, learning from one PDK can be applied to another PDK, or design made from the other PDK. Parasitic extraction data can be converted into a graphical format for display and can be made accessible for inspection and further user review.

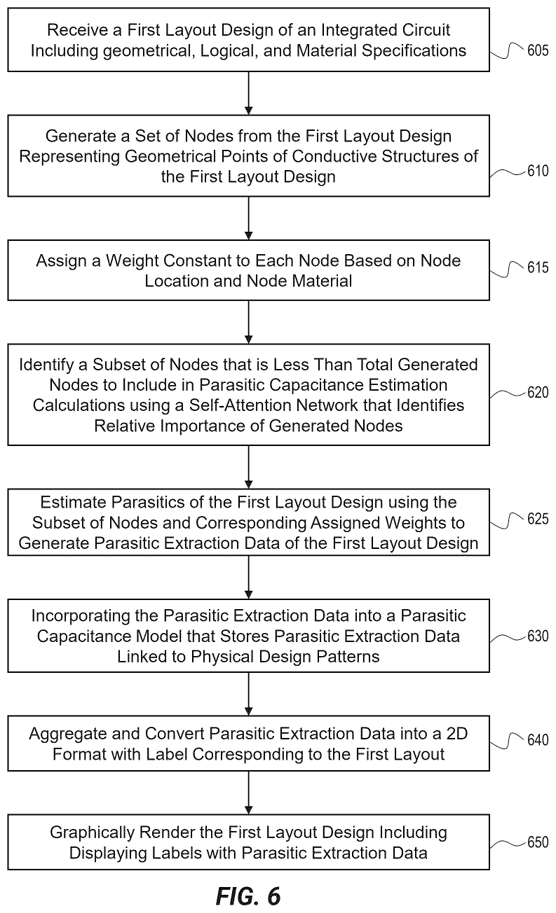

FIG. 6 is a flow chart illustrating another example embodiment herein. In step 605, the process begins with receiving a first layout design of an integrated circuit, including geometrical, logical, and material specifications. For example, a GDS file of a VLSI integrated circuit is received. This component serves as the initial input, providing a representation or specification of the integrated circuit's design. The first layout design can encompass various specifications that define the structure and functionality of the circuit.

In step 610, the system generates a set of nodes from the first layout design, representing geometrical points of conductive structures of the first layout design. This step involves analyzing the layout to determine specific points or nodes that are relevant for performing parasitic extraction. The identification process focuses on nodes that significantly impact the electrical properties of the design, ensuring accurate and efficient calculations, such as by relative distance, geometric feature (corner), and type or thickness of material, among others. Generating a set of nodes can include passing a 2D Graphic Design System file through an encoder network.

In step 615, once the nodes are identified, the system assigns a weight constant to each node based on node location and node material. This weighting process evaluates the importance of each node in relation to the node's position and the material properties. By assigning weights, the system can prioritize nodes that have a greater influence on parasitic values, making the estimation process more efficient.

In step 620, the system identifies a subset of nodes that is less than the total generated nodes to include in parasitic extraction using a self-attention network that identifies the relative importance of generated nodes. The self-attention network analyzes the relationships between nodes, considering their weights and interactions to predict parasitic values. This network leverages machine learning techniques to improve the efficiency of parasitic extraction. Attention networks are known, especially in the human social interaction context, and can be adapted for use herein with geometric points in a rendered physical structure of a logical design being nodes for evaluation in the self-attention network. In other embodiments the system identifies a set of potential parameters corresponding to each node for inclusion in parasitics estimation and identifies a subset of the potential parameters that is a reduction from total potential parameters or a reduction from initially identified parameters.

In step 625, parasitic extraction is performed on the first layout design using the subset of nodes and corresponding assigned weights to generate parasitic extraction data of the first layout design. In step 630, the system incorporates the parasitic extraction data into a machine learning model that stores parasitic extraction data linked to physical design patterns. The machine learning model can serve as a repository, linking the data to specific design segments, facilitating ongoing analysis and optimization of the integrated circuit design.

In step 640 the system aggregates and converts parasitic extraction data into a 2D format with a label corresponding to the first layout. This conversion enables easier visualization and analysis of the data, allowing for a representation of the design for easier user review. Labeled data is then treated as a graph node to capture the relation between neighbors, enhancing the model's ability to learn from diverse datasets and perform labeling across models. In step 650, the system can graphically render the first layout design, including displaying labels with parasitic extraction data. This graphical representation aids in visualizing and analyzing the design, enabling more precise predictions and optimizations.

In other embodiments the machine learning model can be trained on a first process design kit corresponding to the first layout design, and can include performing parasitic extraction on a second layout design from a second process design kit, with the second process design kit being different from the first process design kit. Parasitic extraction data from a given process design kit can be anonymized for use in evaluating subsequent candidate layouts, such as be using geometric conductive structural segments that are a component of standard cell. In other words, for example, standard cells from a given process design kit can be stored as individual components or otherwise limited to wiring segments that repeat in standard cell renderings.

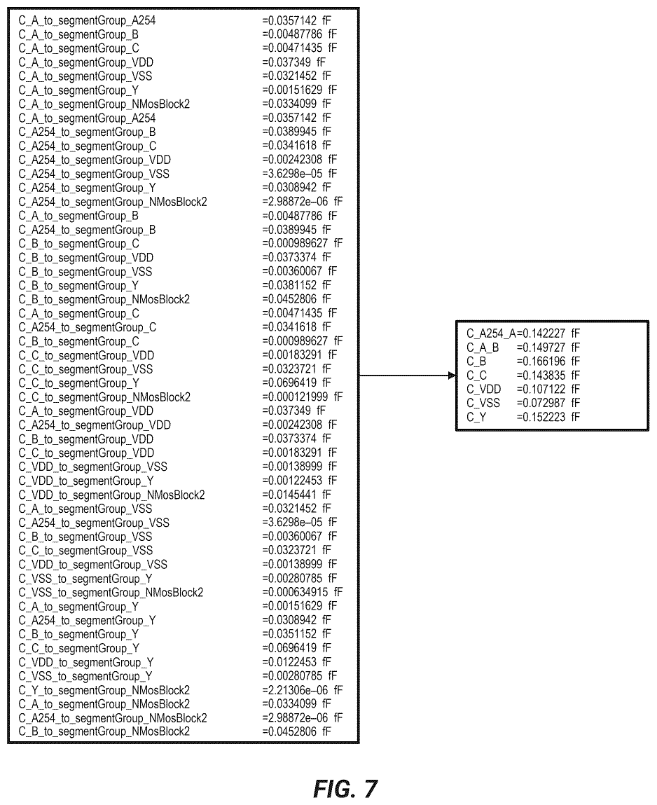

Referring now to FIG. 7, a sample representation of labeled parasitic extraction data is shown in box 705, with a sub-set of the parasitic extraction data highlighted in box 707. As can be appreciated, various candidate layouts will have differing parasitic extraction data values, and results can be sorted or ranked or filtered by various features to display results of interest.

FIG. 8 illustrates geometric point modeling and node selection. FIG. 8A is a perspective view of an example physical layout of wiring for a given circuit, circuit element, or standard cell or portion thereof. FIG. 8B shows identified nodes from geometrical points based on a given design density. FIG. 8C then shows a subset of the nodes selected for use in parasitic extraction.

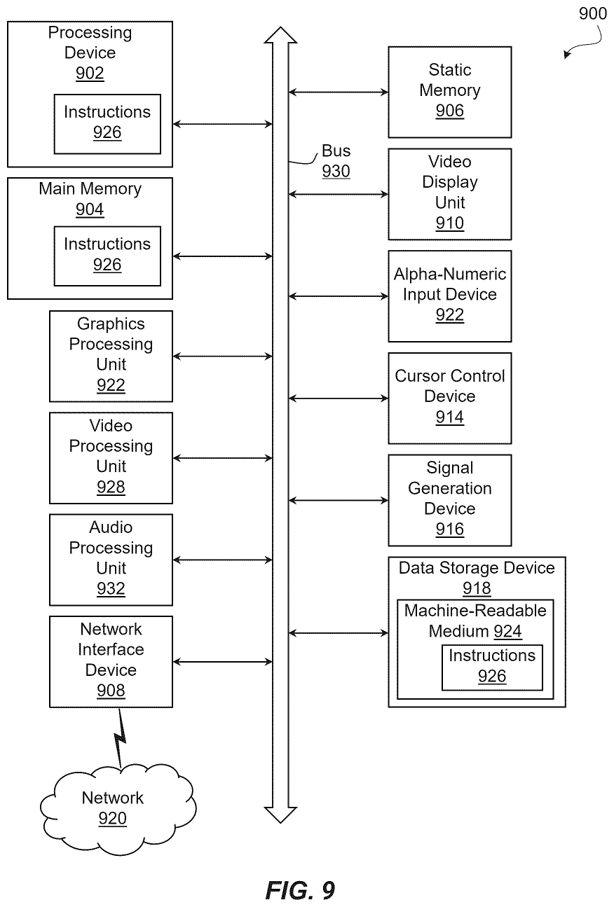

FIG. 9 depicts a representative diagram of an example computer system in which embodiments of the present disclosure may operate.

A storage subsystem of a computer system (such as computer system 900 of FIG. 9) may be used to store the programs and data structures that are used by some or all of the EDA products described herein, and products used for development of cells for the library and for physical and logical design that use the library.

FIG. 9 illustrates an example machine of a computer system 900 within which a set of instructions, for causing the machine to perform any one or more of the methodologies discussed herein, including efficient parasitic extraction and spatial localization in electronic design of an integrated circuit, may be executed. In alternative implementations, the machine may be connected (e.g., networked) to other machines in a LAN, an intranet, an extranet, and/or the Internet. The machine may operate in the capacity of a server or a client machine in a client-server network environment, as a peer machine in a peer-to-peer (or distributed) network environment, or as a server or a client machine in a cloud computing infrastructure or environment.

The machine may be a personal computer (PC), a tablet PC, a set-top box (STB), a Personal Digital Assistant (PDA), a cellular telephone, a web appliance, a server, a network router, a switch or bridge, or any machine capable of executing a set of instructions (sequential or otherwise) that specify actions to be taken by that machine. Further, while a single machine is illustrated, the term “machine” shall also be taken to include any collection of machines that individually or jointly execute a set (or multiple sets) of instructions to perform any one or more of the methodologies discussed herein.

The example computer system 900 includes a processing device 902, a main memory 904 (e.g., read-only memory (ROM), flash memory, dynamic random access memory (DRAM) such as synchronous DRAM (SDRAM), a static memory 906 (e.g., flash memory, static random access memory (SRAM), etc.), and a data storage device 918, which communicate with each other via a bus 930.

Processing device 902 represents one or more processors such as a microprocessor, a central processing unit, or the like. More particularly, the processing device may be complex instruction set computing (CISC) microprocessor, reduced instruction set computing (RISC) microprocessor, very long instruction word (VLIW) microprocessor, or a processor implementing other instruction sets, or processors implementing a combination of instruction sets. Processing device 902 may also be one or more special-purpose processing devices such as an application specific integrated circuit (ASIC), a field programmable gate array (FPGA), a digital signal processor (DSP), network processor, or the like. The processing device 902 may be configured to execute instructions 926 for performing the operations and steps described herein.

The computer system 900 may further include a network interface device 908 to communicate over the network 920. The computer system 900 also may include a video display unit 910 (e.g., a liquid crystal display (LCD) or a cathode ray tube (CRT)), an alphanumeric input device 912 (e.g., a keyboard), a cursor control device 914 (e.g., a mouse), a graphics processing unit 922, a signal generation device 916 (e.g., a speaker), graphics processing unit 922, video processing unit 928, and audio processing unit 932.

The data storage device 918 may include a machine-readable storage medium 924 (also known as a non-transitory computer-readable medium) on which is stored one or more sets of instructions 926 or software embodying any one or more of the methodologies or functions described herein. The instructions 926 may also reside, completely or at least partially, within the main memory 904 and/or within the processing device 902 during execution thereof by the computer system 900, the main memory 904 and the processing device 902 also constituting machine-readable storage media.

In some implementations, the instructions 926 include instructions to implement functionality corresponding to the present disclosure. While the machine-readable storage medium 924 is shown in an example implementation to be a single medium, the term “machine-readable storage medium” should be taken to include a single medium or multiple media (e.g., a centralized or distributed database, and/or associated caches and servers) that store the one or more sets of instructions. The term “machine-readable storage medium” shall also be taken to include any medium that is capable of storing or encoding a set of instructions for execution by the machine and that cause the machine and the processing device 902 to perform any one or more of the methodologies of the present disclosure. The term “machine-readable storage medium” shall accordingly be taken to include, but not be limited to, solid-state memories, optical media, and magnetic media.

Some portions of the preceding detailed description have been presented in terms of algorithms and symbolic representations of operations on data bits within a computer memory. These algorithmic descriptions and representations are the ways used by those skilled in the data processing arts to most effectively convey the substance of their work to others skilled in the art. An algorithm may be a sequence of operations leading to a desired result. The operations are those requiring physical manipulations of physical quantities. Such quantities may take the form of electrical or magnetic signals capable of being stored, combined, compared, and otherwise manipulated. Such signals may be referred to as bits, values, elements, symbols, characters, terms, numbers, or the like.

It should be noted, however, that all of these and similar terms are to be associated with the appropriate physical quantities and are merely convenient labels applied to these quantities. Unless specifically stated otherwise as apparent from the present disclosure, it is appreciated that throughout the description, certain terms refer to the action and processes of a computer system, or similar electronic computing device, that manipulates and transforms data represented as physical (electronic) quantities within the computer system's registers and memories into other data similarly represented as physical quantities within the computer system memories or registers or other such information storage devices.

The present disclosure also relates to an apparatus for performing the operations herein. This apparatus may be specially constructed for the intended purposes, or it may include a computer selectively activated or reconfigured by a computer program stored in the computer. Such a computer program may be stored in a computer readable storage medium, such as, but not limited to, any type of disk including floppy disks, optical disks, CD-ROMs, and magnetic-optical disks, read-only memories (ROMs), random access memories (RAMs), EPROMs, EEPROMs, magnetic or optical cards, or any type of media suitable for storing electronic instructions, each coupled to a computer system bus.

The algorithms and displays presented herein are not inherently related to any particular computer or other apparatus. Various other systems may be used with programs in accordance with the teachings herein, or it may prove convenient to construct a more specialized apparatus to perform the method. In addition, the present disclosure is not described with reference to any particular programming language. It will be appreciated that a variety of programming languages may be used to implement the teachings of the disclosure as described herein.

The present disclosure may be provided as a computer program product, or software, that may include a machine-readable medium having stored thereon instructions, which may be used to program a computer system (or other electronic devices) to perform a process according to the present disclosure. A machine-readable medium includes any mechanism for storing information in a form readable by a machine (e.g., a computer). For example, a machine-readable (e.g., computer-readable) medium includes a machine (e.g., a computer) readable storage medium such as a read only memory (“ROM”), random access memory (“RAM”), magnetic disk storage media, optical storage media, flash memory devices, etc.

In the foregoing disclosure, implementations of the disclosure have been described with reference to specific example implementations thereof. It will be evident that various modifications may be made thereto without departing from the broader spirit and scope of implementations of the disclosure as set forth in the following claims. Where the disclosure refers to some elements in the singular tense, more than one element can be depicted in the figures and like elements are labeled with like numerals. The disclosure and drawings are, accordingly, to be regarded in an illustrative sense rather than a restrictive sense.

1. A method of training a parasitic extraction machine learning model, the method comprising:
receiving a graphic design system file (GDS file) of a very large-scale integration (VLSI) integrated circuit, the graphic design system file including a first layout design of the VLSI integrated circuit, the first layout design including geometrical specifications, logical specifications, and material specifications;
identifying, by a processing device, geometrical locations from the first layout design as nodes for inclusion in parasitic extraction calculations;
assigning a weight to each node based on relative node location and node material;
performing, by the processing device, parasitic extraction on the first layout design using a self-attention network based on the nodes and corresponding assigned weights to generate parasitic extraction data corresponding to geometrical layout segments;
labeling, by the processing device, the geometrical layout segments and linking corresponding parasitic extraction data to the labeled geometrical layout segments; and
incorporating, by the processing device, the parasitic extraction data into a machine learning model that stores parasitic extraction data linked to the labeled geometrical layout segments.

2. The method of claim 1, further comprising:
identifying, by the processing device, intermediate nodes between two end point nodes in a given geometrical structure region and excluding the intermediate nodes from parasitic extraction calculations when the intermediate nodes modify parasitic values of the given geometrical structure region by less than a predetermined threshold value.

3. The method of claim 2, further comprising:
calculating, by the processing device, second parasitic extraction data for the given geometrical structure region by excluding the intermediate nodes from calculation; and
linking, by the processing device, the second parasitic extraction data to the given geometrical structure region and adding the parasitic extraction data to the machine learning model.

4. The method of claim 3, further comprising:
excluding, by the processing device, nodes from parasitic extraction having an assigned weight below a predetermined value.

5. The method of claim 1, further comprising:
accumulating, by the processing device, parasitic extraction data in the machine learning model for a plurality of geometrical layout segments from multiple layout designs such that subsequent performance of parasitic extraction of a candidate layout design using the machine learning model includes use of the stored parasitic extraction data linked to the labeled geometrical layout segments that physically match the geometrical layout segments from the candidate layout design.

6. The method of claim 5, further comprising:
identifying, by the processing device, a particular geometrical layout segment having a pattern appearing repeatedly from the first layout design and having corresponding parasitic extraction data values that vary relative to each other; and
selecting, by the processing device, a representative parasitic extraction value for the particular geometrical layout segment.

7. The method of claim 5, further comprising:
updating, by the processing device, the machine learning model using layout designs corresponding to a first process design kit; and
performing, by the processing device, parasitic extraction for the candidate layout design using the machine learning model and stored parasitic extraction data from the first process design kit, the candidate layout design generated based on a second process design kit.

8. A system comprising:
a memory storing instructions; and
a processing device, coupled with the memory and configured to execute the instructions, the instructions when executed cause the processing device to:
receive a graphic design system file (GDS file) of a very large-scale integration (VLSI) integrated circuit, the graphic design system file including a first layout design of the VLSI integrated circuit, the first layout design including geometrical specifications, logical specifications, and material specifications;
identify geometrical locations from the first layout design as nodes for inclusion in parasitic extraction calculations;
assign a weight to each node based on relative node location and node material;
perform parasitic extraction on the first layout design using a self-attention network based on the nodes and corresponding assigned weights to generate parasitic extraction data corresponding to geometrical layout segments;
label the geometrical layout segments and link corresponding parasitic extraction data to the labeled geometrical layout segments; and
incorporate the parasitic extraction data into a machine learning model that stores parasitic extraction data linked to the labeled geometrical layout segments.

9. The system of claim 8, wherein the instructions further cause the processing device to:
identify intermediate nodes between two end point nodes in a given geometrical structure region and excluding the intermediate nodes from parasitic extraction calculations when the intermediate nodes modify parasitic values of the given geometrical structure region by less than a predetermined threshold value.

10. The system of claim 9, wherein the instructions further cause the processing device to:
calculate second parasitic extraction data for the given geometrical structure region by excluding the intermediate nodes from calculation; and
link the second parasitic extraction data to the given geometrical structure region and add the parasitic extraction data to the machine learning model.

11. The system of claim 9, wherein the instructions further cause the processing device to:
exclude nodes from parasitic extraction having an assigned weight below a predetermined value.

12. The system of claim 8, wherein the instructions further cause the processing device to:
accumulate parasitic extraction data in the machine learning model for a plurality of geometrical layout segments from multiple layout designs such that subsequent performance of parasitic extraction of a candidate layout design using the machine learning model includes use of the stored parasitic extraction data linked to the labeled geometrical layout segments that physically match the geometrical layout segments from the candidate layout design.

13. The system of claim 12, wherein the instructions further cause the processing device to:
identify a particular geometrical layout segment having a pattern appearing repeatedly from the first layout design and having corresponding parasitic extraction data values that vary relative to each other; and
select a representative parasitic extraction value for the particular geometrical layout segment.

14. The system of claim 12, wherein the instructions further cause the processing device to:
update the machine learning model using layout designs corresponding to a first process design kit; and
perform parasitic extraction for the candidate layout design using the machine learning model and stored parasitic extraction data from the first process design kit, the candidate layout design generated based on a second process design kit.

15. A non-transitory computer readable medium comprising stored instructions, which when executed by a processing device, cause the processing device to:
receive a graphic design system file (GDS file) of a very large-scale integration (VLSI) integrated circuit, the graphic design system file includes a first layout design of the VLSI integrated circuit, the first layout design including geometrical specifications, logical specifications, and material specifications;
identify geometrical locations from the first layout design as nodes for inclusion in parasitic extraction calculations;
assign a weight to each node based on relative node location and node material;
perform parasitic extraction on the first layout design using a self-attention network based on the nodes and corresponding assigned weights to generate parasitic extraction data corresponding to geometrical layout segments;
label the geometrical layout segments and link corresponding parasitic extraction data to the labeled geometrical layout segments; and
incorporate the parasitic extraction data into a machine learning model that stores parasitic extraction data linked to the labeled geometrical layout segments.

16. The non-transitory computer readable medium of claim 15, wherein the instructions further cause the processing device to:
identify intermediate nodes between two end point nodes in a given geometrical structure region and excluding the intermediate nodes from parasitic extraction calculations when the intermediate nodes modify parasitic values of the given geometrical structure region by less than a predetermined threshold value; and
exclude nodes from parasitic extraction having an assigned weight below a predetermined value.

17. The non-transitory computer readable medium of claim 16, wherein the instructions further cause the processing device to:
accumulate parasitic extraction data in the machine learning model for a plurality of geometrical layout segments from multiple layout designs such that subsequent performance of parasitic extraction of a candidate layout design using the machine learning model includes use of the stored parasitic extraction data linked to the labeled geometrical layout segments that physically match the geometrical layout segments from the candidate layout design.

18. The non-transitory computer readable medium of claim 17, wherein the instructions further cause the processing device to:
identify a particular geometrical layout segment having a pattern appearing repeatedly from the first layout design and having corresponding parasitic extraction data values that vary relative to each other; and
select a representative parasitic extraction value for the particular geometrical layout segment.

19. The non-transitory computer readable medium of claim 18, wherein the instructions further cause the processing device to:
calculate second parasitic extraction data for the given geometrical structure region by excluding the intermediate nodes from calculation; and
link the second parasitic extraction data to the given geometrical structure region and add the parasitic extraction data to the machine learning model.

20. The non-transitory computer readable medium of claim 19, wherein the instructions further cause the processing device to:
update the machine learning model using layout designs corresponding to a first process design kit; and
perform parasitic extraction for the candidate layout design using the machine learning model and stored parasitic extraction data from the first process design kit, the candidate layout design generated based on a second process design kit.
